(19) United States
(12) Patent Application Publication
(10) Pub. No.: US 2025/0107236 A1
(43) Pub. Date: Mar. 27, 2025

(54) ELECTRONIC DEVICE AND METHOD OF MANUFACTURING THE SAME

(71) Applicant: InnoLux Corporation, Miao-Li County (TW)

(72) Inventors: Chandra LIUS, Miao-Li County (TW); Jhe-Ciou JHU, Miao-Li County (TW); Chung-Wen YEN, Miao-Li County (TW)

(21) Appl. No.: 18/810,873

(22) Filed: Aug. 21, 2024

(30) Foreign Application Priority Data
Sep. 26, 2023 (CN) 202311248669.8

(51) Int. Cl. H01L 27/12; H01L 29/786

(52) U.S. Cl. CPC H10D 86/60; H10D 30/6755; H10D 86/0221; H10D 86/423

(57) ABSTRACT

An electronic device is provided. The electronic device includes a substrate, a buffer layer, an oxide semiconductor layer, a first insulating layer, and a gate electrode. The buffer layer is disposed on the substrate. The oxide semiconductor layer is disposed on the buffer layer and has a first part and a second part adjacent to the first part. The first insulating layer is disposed on the oxide semiconductor layer. The gate electrode is disposed on the first insulating layer and overlapped with the first part of the oxide semiconductor layer. Moreover, an intensity of SiN— at an interface between the first part and the first insulating layer is greater than an intensity of SiN— at an interface between the first part and the buffer layer in a spectrum measured by TOF-SIMS. A method of manufacturing an electronic device is also provided.

### CROSS REFERENCE TO RELATED APPLICATIONS

This application claims the benefit of China Application No. 202311248669.8, filed Sep. 26, 2023, the entirety of which is incorporated by reference herein.

### BACKGROUND

### Technical Field

The present disclosure is related to an electronic device, and in particular it is related to an electronic device having a thin-film transistor structure and a method of manufacturing the same.

### Description of the Related Art

Electronic devices such as tablet computers, notebook computers, smartphones, monitors, and televisions have become indispensable necessities in modern society. With the ongoing development of these portable electronic devices, consumers have high expectations regarding the quality, functionality or price of these products.

Electronic devices usually include electronic components with driving functions, such as thin-film transistor structures. Metal oxide thin-film transistors have been widely used because of their high electron mobility and low off-state current.

However, since metal oxide thin-film transistors undergo multiple heating and annealing processes during the manufacturing process, these processes can easily lead to poor positive-bias-temperature stress (PBTS) performance of thin-film transistors, thereby affecting the reliability of electronic devices.

Therefore, further improving the performance of driving components of electronic devices is still one of the current research topics in the industry.

### SUMMARY

In accordance with some embodiments of the present disclosure, an electronic device is provided. The electronic device includes a substrate, a buffer layer, an oxide semiconductor layer, a first insulating layer, and a gate electrode. The buffer layer is disposed on the substrate. The oxide semiconductor layer is disposed on the buffer layer and has a first part and a second part adjacent to the first part. The first insulating layer is disposed on the oxide semiconductor layer. The gate electrode is disposed on the first insulating layer and overlapped with the first part of the oxide semiconductor layer. Moreover, an intensity of SiN— at an interface between the first part and the first insulating layer is greater than an intensity of SiN— at an interface between the first part and the buffer layer in a spectrum measured by TOF-SIMS.

In accordance with some embodiments of the present disclosure, a method of manufacturing an electronic device is also provided. The method includes the following steps: providing a substrate; forming a buffer layer on the substrate; and forming an oxide semiconductor layer on the buffer layer. The oxide semiconductor layer has a first part and a second part adjacent to the first part. The method also includes the following steps: performing an N2 plasma treatment on a surface of the oxide semiconductor layer; forming a first insulating layer on the oxide semiconductor layer; and forming a gate electrode on the first insulating layer. Moreover, the gate electrode is overlapped with the first part of the oxide semiconductor layer.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a cross-sectional diagram of an electronic device in accordance with some embodiments of the present disclosure;

FIG. 2 is the result of analyzing an electronic device by a time-of-flight secondary ion mass spectrometer (TOF-SIMS) in accordance with some embodiments of the present disclosure;

FIG. 3 is the result of analyzing an electronic device by a TOF-SIMS in accordance with some embodiments of the present disclosure;

FIG. 4 is the result of analyzing an electronic device by a TOF-SIMS in accordance with some embodiments of the present disclosure;

FIG. 5 is the result of analyzing an electronic device by a TOF-SIMS in accordance with some embodiments of the present disclosure;

FIG. 6 is a cross-sectional diagram of an electronic device in accordance with some embodiments of the present disclosure.

### DETAILED DESCRIPTION

The electronic device and the method of manufacturing the same according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean +/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

Moreover, in accordance with the embodiments of the present disclosure, an optical microscope (OM), a scanning electron microscope (SEM), a film thickness profiler (α-step), an ellipsometer or another suitable method may be used to measure the thickness, length or width of each element, or distance or angle between elements. Specifically, in accordance with some embodiments, a scanning electron microscope can be used to obtain cross-sectional images of the structure and measure the thickness, length or width of each element, or distance or angle between elements.

When “In the mass spectrum measured by TOF-SIMS, the intensity of a certain negative ion at a specific position is greater than the intensity of the certain negative ion at another specific position” is described, it contains a situation in which the certain negative ion is not substantially included at another specific location.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiment of the present disclosure, an electronic device is provided, including an oxide semiconductor layer treated with a specific process, thereby improving the stability of the positive-bias-temperature stress (PBTS) performance of the thin-film transistor. The reliability of the electronic device therefore can be improved.

In accordance with the embodiments of the present disclosure, the electronic device may include a display device, a tiled device, a touch electronic device, a sensing device, a curved electronic device or a non-rectangular electronic device, but it is not limited thereto. The electronic device may include, for example, liquid crystal, light emitting diode, fluorescence, phosphor, other suitable display media, or a combination thereof, but it is not limited thereto. The display device may be a non-self-luminous display device or a self-luminous display device. The electronic device may include passive components and active components, such as capacitors, resistors, inductors, diodes, transistors, etc. The diode may include a light-emitting diode (LED) or a photodiode. The light-emitting diode may include, for example, an organic light-emitting diode (OLED), a mini light-emitting diode (mini LED), a micro-light-emitting diode (micro LED) or a quantum dot light-emitting diode (quantum dot LED), but it is not limited thereto. The tiled device may be, for example, a tiled display device, but it is not limited thereto. It should be noted that the electronic device can be any combination of the above, but it is not limited thereto. In addition, the electronic device may be a bendable or flexible electronic device. In addition, the shape of the electronic device may be a rectangular shape, a circular shape, a polygonal shape, a shape with curved edges, or other suitable shapes. The electronic device may have a peripheral system such as a driving system, a control system, a light source system, a shelf system, etc. to support a display device or tiled device. For convenience of explanation, the electronic device will be described below as a display device, but the present disclosure is not limited thereto.

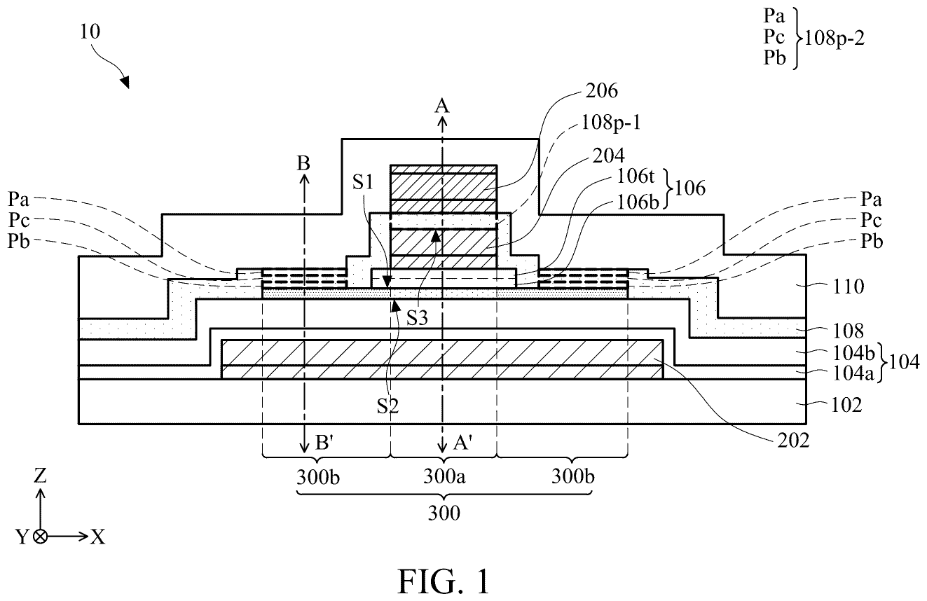

Please refer to FIG. 1, which is a cross-sectional diagram of an electronic device 10 in accordance with some embodiments of the present disclosure. It should be understood that, for clarity of explanation, some components of the electronic device 10 may be omitted in the drawings, and only some components are schematically illustrated. In accordance with some embodiments, additional features may be added to the electronic device 10 described below.

As described the above, the electronic device 10 may be a display device. As shown in FIG. 1, the electronic device 10 may include a substrate 102, a buffer layer 104, an oxide semiconductor layer 300, an insulating layer 106 and a gate electrode 204.

In accordance with some embodiments, the substrate 102 may serve as a substrate carrying an active driving circuit and/or a passive driving circuit. For example, as shown in FIG. 1, the electronic device 10 may include a thin-film transistor formed of a metal layer 202 (which can also serve as a gate electrode), an oxide semiconductor layer 300, an insulating layer 106 and a gate electrode 204. In accordance with some embodiments, the thin-film transistor may include a driving transistor, a switching transistor, a reset transistor, a transistor amplifier, or another suitable thin-film transistor. In addition, it should be understood that although the thin-film transistor illustrated in the drawings is a dual gate (double gate) thin-film transistor, the thin-film transistor may also be a top gate thin-film transistor or a bottom gate thin-film transistor according to different embodiments. Furthermore, in accordance with some embodiments, the electronic device 10 may further include data lines, scan lines, touch signal lines, common voltage lines, power lines or other wirings disposed on the substrate 102 as needed, but it is not limited thereto.

The substrate 102 may include a rigid substrate or a flexible substrate. In accordance with some embodiments, the material of the substrate 102 may include glass, quartz, sapphire, polyimide (PI), polycarbonate (PC), polyethylene terephthalate (PET), polypropylene (PP), another suitable material or a combination thereof, but it is not limited thereto. Furthermore, in accordance with some embodiments, the substrate 102 may include a metal-glass fiber composite plate or a metal-ceramic composite plate, but it is not limited thereto. In addition, the substrate 102 may be a light-transmitting substrate, a semi-light-transmitting substrate, or an opaque substrate.

In accordance with some embodiments, the electronic device 10 may further include a metal layer 202, and the metal layer 202 may be disposed on the substrate 102. Furthermore, the metal layer 202 may be overlapped with the oxide semiconductor layer 300. The metal layer 202 can serve as a lower gate electrode of the thin-film transistor, but it is not limited thereto. The metal layer 202 may have a single-layer or multi-layer structure. For example, as shown in FIG. 1, in accordance with some embodiments, the metal layer 202 may have a double-layer structure, but it is not limited thereto.

In accordance with some embodiments, the material of the metal layer 202 may include a conductive material, such as copper (Cu), titanium (Ti), silver (Ag), gold (Au), tin (Sn), aluminum (Al), molybdenum (Mo), tungsten (W), chromium (Cr), nickel (Ni), platinum (Pt), palladium (Pd), alloys of the aforementioned metals, another suitable conductive material, or a combination thereof, but it is not limited thereto. In accordance with some embodiments, the metal layer 202 may be a double-layer structure (Ti/Cu) with a lower layer of titanium and an upper layer of copper, but it is not limited thereto.

The buffer layer 104 may be disposed on the substrate 102, and the buffer layer 104 may be disposed between the metal layer 202 and the oxide semiconductor layer 300. In accordance with some embodiments, the buffer layer 104 may also be conformally disposed on the metal layer 202. The buffer layer 104 can alleviate the strain difference between the insulating layer 108 and the substrate 102. Moreover, the buffer layer 104 may have a single-layer or multi-layer structure. For example, as shown in FIG. 1, in accordance with some embodiments, the buffer layer 104 may have a double-layer structure formed by a sub-layer 104a and a sub-layer 104b.

In accordance with some embodiments, the material of the buffer layer 104 may include silicon nitride, silicon oxide, silicon oxynitride, another suitable buffer material, or a combination thereof, but it is not limited thereto. In accordance with some embodiments, the sub-layer 104a of buffer layer 104 includes silicon nitride and the sub-layer 104b of buffer layer 104 includes silicon oxide.

The oxide semiconductor layer 300 may be disposed on the buffer layer 104, and the oxide semiconductor layer 300 may have a first part 300a and second parts 300b adjacent to the first part 300a. Specifically, the oxide semiconductor layer 300 may have two second parts 300b respectively disposed on both sides of the first part 300a. The first part 300a may be overlapped with the gate electrode 204 in the normal direction of the substrate 102 (for example, the Z direction in the figure), and the second parts 300b may be not overlapped with the gate electrode 204 in the normal direction of the substrate 102. The first part 300a can serve as a channel region, and the second part 300b can serve as a doped region. The doped region may have appropriate dopant so that the second parts 300b have conductive properties (e.g., n-type or p-type). In accordance with some embodiments, the second part 300b can serve as a source contact and can be further electrically connected to a source electrode (not illustrated).

In accordance with some embodiments, the oxide semiconductor layer 300 may include indium (In) and gallium (Ga). Further, in accordance with some embodiments, the material of the oxide semiconductor layer 300 may include indium gallium zinc oxide (IGZO), indium gallium oxide (IGO), indium gallium zinc tin oxide (IGZTO), another suitable material or a combination thereof, but it is not limited thereto.

The insulating layer 106 may be disposed on the oxide semiconductor layer 300. In accordance with some embodiments, the insulating layer 106 can serve as a gate insulating layer for a thin-film transistor. In accordance with some embodiments, in the normal direction of the substrate 102 (e.g., the Z direction in the figure), the insulating layer 106 may be overlapped with the first part 300a of the oxide semiconductor layer 300 and be partially overlapped with the second part 300b of the oxide semiconductor layer 300. Furthermore, the insulating layer 106 may have an upper part 106t and a lower part 106b, and the upper part 106t is disposed above the lower part 106b. In accordance with some embodiments, the upper part 106t and the lower part 106b may be distinguished by half the thickness of the insulating layer 106.

In accordance with some embodiments, the material of the insulating layer 106 may include silicon oxide, silicon nitride, silicon oxynitride, another suitable material, or a combination thereof, but it is not limited thereto.

Furthermore, the gate electrode 204 may be disposed on the insulating layer 106 and overlapped with the first part 300a of the oxide semiconductor layer 300. The gate electrode 204 may have a single-layer or multi-layer structure. For example, as shown in FIG. 1, in accordance with some embodiments, the gate electrode 204 may have a double-layer structure, but it is not limited thereto.

In accordance with some embodiments, the material of the gate electrode 204 may include a conductive material, such as copper (Cu), titanium (Ti), silver (Ag), gold (Au), tin (Sn), aluminum (Al), molybdenum (Mo), tungsten (W), chromium (Cr), nickel (Ni), platinum (Pt), palladium (Pd), alloys of the aforementioned metals, another suitable conductive material or a combination thereof, but it is not limited thereto. In accordance with some embodiments, the gate electrode 204 may be a double-layer structure (Ti/Cu) with a lower layer of titanium and an upper layer of copper, but it is not limited thereto.

In accordance with some embodiments, the electronic device 10 may further include an insulating layer 108, and the insulating layer 108 may be disposed on the gate electrode 204. In detail, the insulating layer 108 may be conformally disposed on the buffer layer 104, the oxide semiconductor layer 300, the insulating layer 106 and the gate electrode 204. Moreover, the insulating layer 108 may have a third part 108p-1 that is overlapped with the gate electrode 204 in the normal direction of the substrate 102 (e.g., the Z direction in the figure). The insulating layer 108 may have a fourth part 108p-2 that is overlapped with the second part 300b of the oxide semiconductor layer 300 in the normal direction of the substrate 102. The fourth part 108p-2 has an upper portion Pa, a lower portion Pb, and a middle portion Pc between the upper portion Pa and the lower portion Pb. In accordance with some embodiments, the thickness of the fourth part 108p-2 of the insulating layer 108 can be divided into three equal parts, which are respectively defined from top to bottom as the upper portion Pa, the middle portion Pc, and the lower portion Pb.

In accordance with some embodiments, the material of the insulating layer 108 may include silicon oxynitride (SiON), another suitable material, or a combination thereof, but it is not limited thereto.

In accordance with some embodiments, the electronic device 10 may further include a metal layer 206, and the metal layer 206 may be disposed on the insulating layer 108. In accordance with some embodiments, the metal layer 206 may be overlapped with the gate electrode 204 in a normal direction of the substrate 102 (e.g., the Z direction in the figure). The metal layer 206 may have a single-layer or multi-layer structure. For example, as shown in FIG. 1, in accordance with some embodiments, the metal layer 206 may have a three-layer structure, but it is not limited thereto. In accordance with some embodiments, the metal layer 206 can serve as a drain contact and can be further electrically connected to a drain electrode (not illustrated).

In accordance with some embodiments, the material of the metal layer 206 may include a metal conductive material, a transparent conductive material, another suitable material, or a combination thereof, but it is not limited thereto. The metal conductive material may include, for example, copper (Cu), titanium (Ti), silver (Ag), gold (Au), tin (Sn), aluminum (Al), molybdenum (Mo), tungsten (W), chromium (Cr), nickel (Ni), platinum (Pt), palladium (Pd), alloys of the aforementioned metals, another suitable conductive material or a combination thereof, but it is not limited thereto. The transparent conductive material may include, for example, transparent conductive oxide (TCO). The transparent conductive oxide, for example, may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), another suitable transparent conductive material, or a combination thereof, but it is not limited thereto. In accordance with some embodiments, the metal layer 206 may be a three-layer structure formed of titanium, copper and indium tin oxide (Ti/Cu/ITO), but it is not limited thereto.

In addition, in accordance with some embodiments, the electronic device 10 may further include an insulating layer 110, and the insulating layer 110 may be disposed on the metal layer 206. In detail, the insulating layer 110 may be conformally disposed on the insulating layer 108 and the metal layer 206.

In accordance with some embodiments, the material of the insulating layer 110 may include silicon oxide, silicon nitride, silicon oxynitride, another suitable material, or a combination thereof, but it is not limited thereto.

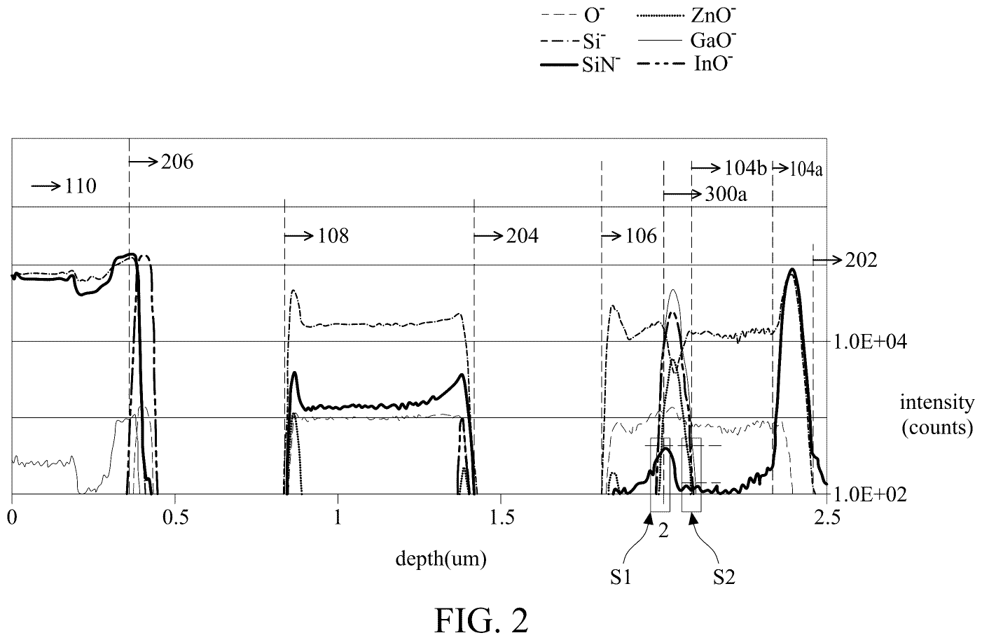

Next, please refer to FIG. 2, which is the result of analyzing the electronic device 10 by a time-of-flight secondary ion mass spectrometer (TOF-SIMS) in accordance with some embodiments of the present disclosure. Specifically, TOF-SIMS can bombard the surface of the sample to be measured by incident ions with energy, ejecting atoms in the target area to generate secondary ions. The secondary ions have different flight speeds due to differences in mass. TOF-SIMS can distinguish ions with different charge-to-mass ratios for composition analysis, and TOF-SIMS can obtain concentration information on the depth profile of different elements in the sample.

FIG. 2 shows the TOF-SIMS analysis result of the electronic device 10 obtained corresponding to the tangent line A-A′ in FIG. 1. The vertical dotted lines in the figure mark the positions of different layers in the electronic device 10. For example, along the tangent line A-A′, the order of the elements from shallower to deeper depth is the insulating layer 110, the metal layer 206, the insulating layer 108, the gate electrode 204, the insulating layer 106, the oxide semiconductor layer 300 (the first part 300a), the sub-layer 104b of the buffer layer 104, and the sub-layer 104a of the buffer layer 104 and metal layer 202. The horizontal axis in the figure is the depth of the structure being analyzed, and the vertical axis is the signal intensity of the received ions, in counts. However, the relative magnitude of the signal intensity of the same secondary ion at different depths can also be understood equivalently as the relative magnitude of the ion concentration of the same secondary ion at different depths. Furthermore, the measurement was performed in the negative ion mode of TOF-SIMS, so the ions are all negatively charged. It should be understood that, for clarity of explanation, not all measured ion species are depicted in the figures.

As shown in FIG. 2, in the mass spectrum measured by TOF-SIMS, the intensity of SiN— at the interface S1 between the first part 300a of the oxide semiconductor layer 300 and the insulating layer 106 is greater than the intensity of SiN— at the interface S2 between the first part 300a and the buffer layer 104 (e.g., sub-layer 104b). In other words, the SiN— concentration at the interface S1 between the first part 300a of the oxide semiconductor layer 300 (e.g., the channel region) and the insulating layer 106 is greater than the SiN— concentration at the interface S2 between the first part 300a and the buffer layer 104. The aforementioned interface S1 and interface S2 are defined based on the position of half of the InO— signal peak value.

It should be noted that the interface S1 has a relatively large SiN— intensity, indicating that the interface S1 between the first part 300a of the oxide semiconductor layer 300 (such as the channel region) and the insulating layer 106 has SiN bonding. SiN bonding can repair defects on the surface of the oxide semiconductor layer 300, such as passivating dangling bonds, thereby improving the stability of the positive-bias-temperature stress (PBTS) performance of the thin-film transistor. The reliability of the electronic device 10 is therefore improved.

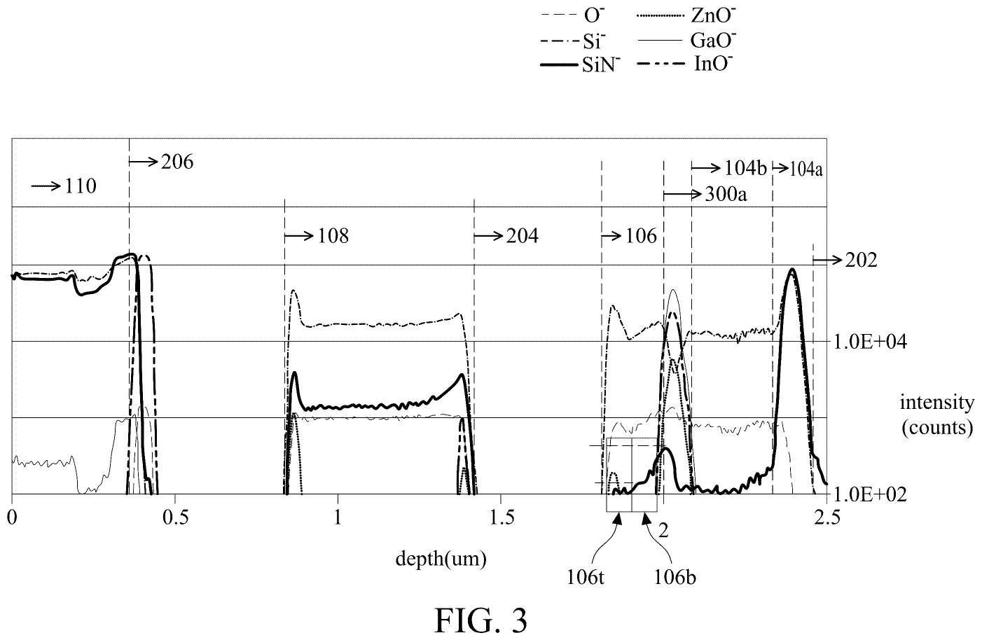

Next, please refer to FIG. 1 and FIG. 3. FIG. 3 is the result of analyzing the electronic device 10 by a TOF-SIMS in accordance with some other embodiments of the present disclosure. FIG. 3 also shows the TOF-SIMS analysis result of the electronic device 10 obtained corresponding to the tangent line A-A′ in FIG. 1.

The insulating layer 106 may have an upper part 106t and a lower part 106b, and in the mass spectrum measured by TOF-SIMS, the intensity of SiN— in the lower part 106b is greater than the intensity of SiN— in the upper part 106t. In other words, the SiN— concentration of the lower part 106b of the insulating layer 106 is greater than the SiN— concentration of the upper part 106t. As described above, half the thickness of the insulating layer 106 can be used to distinguish the upper part 106t and the lower part 106b.

Furthermore, it should be understood that in accordance with some embodiments, “the intensity of SiN— in the lower part 106b is greater than the intensity of SiN— in the upper part 106t” means that the intensity of SiN— at any point in the lower part 106b of the insulating layer 106 is greater than the intensity of SiN— at any point in the upper 106t. In accordance with some other embodiments, “the intensity of SiN— in the lower part 106b is greater than the intensity of SiN— in the upper part 106t” means that the intensity of SiN— at the half-thickness position of the lower portion 106b of the insulating layer 106 is greater than the strength of SiN— at the half-thickness position of the upper portion 106t. In accordance with some other embodiments, “the intensity of SiN— in the lower part 106b is greater than the intensity of SiN— in the upper part 106t” means that the maximum intensity value of SiN— in the lower part 106b of the insulating layer 106 is greater than the maximum intensity value of SiN— in the upper part 106t.

It is noted that the lower part 106b of the insulating layer 106 has a relatively large SiN— intensity. That is, the part of the insulating layer 106 closer to the oxide semiconductor layer 300 has a relatively large SiN— intensity, so that the oxygen vacancies at the interface between the insulating layer 106 and the oxide semiconductor layer 300 are relatively reduced. Therefore, the stability of the positive-bias-temperature stress (PBTS) performance of the thin-film transistor can be improved, thereby improving the reliability of the electronic device 10.

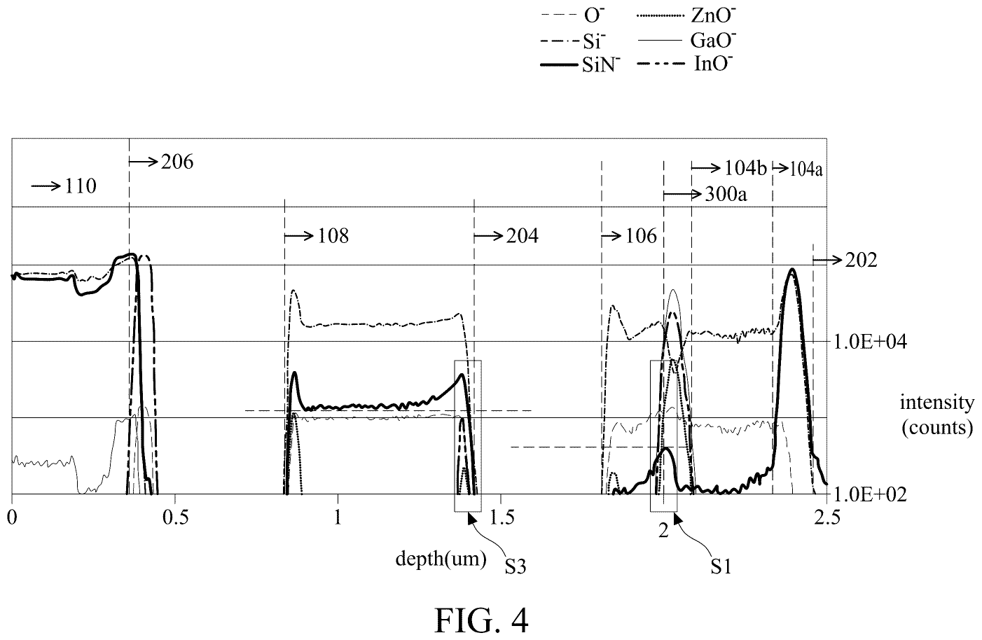

Next, please refer to FIG. 1 and FIG. 4. FIG. 4 is the result of analyzing the electronic device 10 by a TOF-SIMS in accordance with some other embodiments of the present disclosure. FIG. 4 also shows the TOF-SIMS analysis result of the electronic device 10 obtained corresponding to the tangent line A-A′ in FIG. 1.

The insulating layer 108 has a third part 108p-1 that is overlapped with the gate electrode 204. In the mass spectrum measured by TOF-SIMS, the intensity of SiN— at the interface S3 between the third part 108p-1 and the gate electrode 204 is greater than the intensity of SiN— at the interface S1 between the first part 300a of the oxide semiconductor layer 300 and the insulating layer 106. In other words, the SiN-concentration at the interface S3 between the third part 108p-1 of the insulating layer 108 and the gate electrode 204 is greater than the SiN-concentration at the interface S1 between the first part 300a (e.g., the channel region) of the oxide semiconductor layer 300 and the insulating layer 106. The aforementioned interface S1 is defined by the position of half of the InO-signal peak value, and the interface S3 is defined by the position of half of the Si-signal peak value.

It is noted that the interface S3 has a greater SiN— intensity than the interface S1, which means that the SiN-concentration of the insulating layer 108 in the channel region is greater than the SiN-concentration of the interface between the insulating layer 106 and the oxide semiconductor layer 300 (the oxygen content is relatively low), so it can reduce the peeling between the insulating layer 108 and the gate electrode 204, or can prevent the oxidation of the gate electrode 204 from causing problems such as an increase in wiring impedance, thereby improving the electronic device 10 reliability.

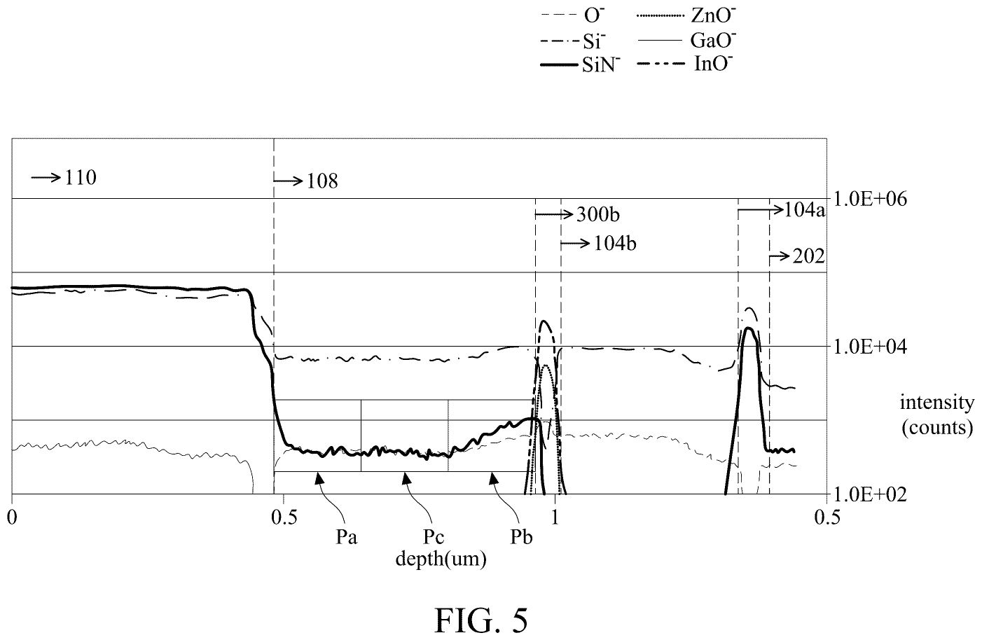

Next, please refer to FIG. 1 and FIG. 5. FIG. 5 is the result of analyzing the electronic device 10 by a TOF-SIMS in accordance with some other embodiments of the present disclosure. FIG. 5 shows the TOF-SIMS analysis result of the electronic device 10 corresponding to the tangent line B-B′ in FIG. 1. The vertical dotted lines in the figure mark the positions of different layers in the electronic device 10. For example, along the tangent line B-B′, the order of the elements from shallower to deeper depth is the insulating layer 110, the insulating layer 108, the oxide semiconductor layer 300 (the second part 300b), the sub-layer 104b of the buffer layer 104, the sub-layer 104a of the buffer layer 104 and the metal layer. 202.

The insulating layer 108 has a fourth part 108p-2 that is overlapped with the second part 300b of the oxide semiconductor layer 300. The fourth part 108p-2 has an upper portion Pa, a lower portion Pb, and a middle portion Pc disposed between the upper portion Pa and the lower portion Pb. In the mass spectrum measured by TOF-SIMS, the intensity of SiN— in the lower portion Pb is greater than the intensity of SiN— in the middle portion Pc. In other words, the SiN-concentration of the lower portion Pb of the fourth part 108p-2 of the insulating layer 108 is greater than the SiN-concentration of the middle portion Pc. Furthermore, in accordance with some embodiments, the intensity (concentration) of SiN— in the lower portion Pb is also greater than the intensity (concentration) of SiN— in the upper portion Pa. As described above, the thickness of the fourth part 108p-2 can be divided into three equal parts, which are respectively defined from top to bottom as the upper portion Pa, the middle portion Pc and the lower portion Pb. Furthermore, the interface of the upper portion Pa of the insulating layer 108 is defined by the position where the O— signal starts, and the interface of the lower portion Pb of the insulating layer 108 is defined by the position of half of the peak value of the InO— signal.

In addition, it should be understood that in accordance with some embodiments, “the intensity of SiN— in the lower portion Pb is greater than the intensity of SiN— in the middle portion Pc” means that the intensity of SiN— at any point of the lower portion Pb of the insulating layer 108 is greater than the intensity of SiN— at any point in the middle portion Pc. In accordance with some other embodiments, “the intensity of SiN— in the lower portion Pb is greater than the intensity of SiN— in the middle portion Pc” means that the intensity of SiN— at a position half the thickness of the lower portion Pb of the insulating layer 108 is greater than the intensity of SiN— at a position half the thickness of the middle portion Pc. In accordance with some embodiments, “the intensity of SiN— in the lower portion Pb is greater than the intensity of SiN— in the middle portion Pc” means that the maximum intensity value of SiN— in the lower portion Pb of the insulating layer 108 is greater than the maximum intensity value of SiN— in the middle portion Pc.

It is noted that that since the oxide semiconductor layer 300 undergoes several heating and annealing processes, the free carriers of the second part 300b (e.g., the doped region) of the oxide semiconductor layer 300 that is not covered by the insulating layer 106 will decrease, causing the conductivity to decrease. However, with the aforementioned arrangement (the lower portion Pb of the fourth part 108p-2 of the insulating layer 108 has a relatively large SiN— intensity), the fourth part 108p-2 of the insulating layer 108 has a relatively large SiN— intensity in the portion closer to the oxide semiconductor layer 300, so that the free carriers at the interface between the fourth part 108p-2 of the insulating layer 108 and the second part 300b (e.g., doped region) of the oxide semiconductor layer 300 will increase, thereby improving the conductivity of the second part 300b of the oxide semiconductor layer 300 or repairing defects on the surface of the oxide semiconductor layer 300.

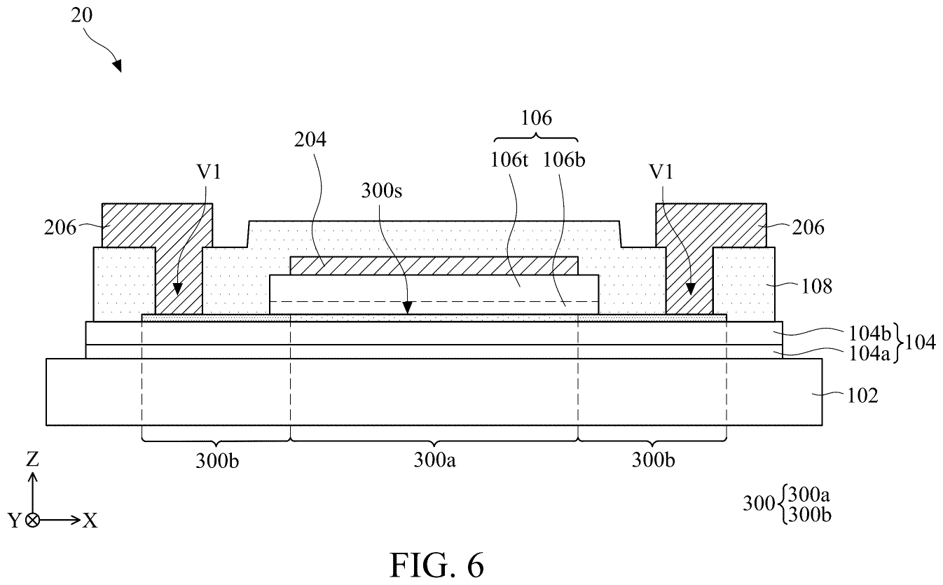

Next, please refer to FIG. 6, which is a cross-sectional diagram of an electronic device 20 in accordance with some other embodiments of the present disclosure. It should be understood that, for clarity of explanation, some components of the electronic device 20 may be omitted in the drawings, and only some components are schematically illustrated. In accordance with some embodiments, additional features may be added to the electronic device 20 described below. It should be understood that the same or similar components or elements in above and below contexts are represented by the same or similar reference numerals. The materials and functions of these components or elements are the same or similar to those described above, and thus will not be repeated in the following description.

In addition, the following will take the electronic device 20 as an example to illustrate the manufacturing method of the electronic device. Although the structures of the electronic device 20 and the electronic device 10 are not exactly the same, the same or similar manufacturing methods are also applicable to the electronic device 10. One with ordinary skill in the art can make corresponding adjustments according to different structures. It should be understood that, in accordance with some embodiments, additional operation steps may be provided before, during, and/or after the manufacturing method of the electronic device 20. In accordance with some embodiments, some of the operation steps described may be replaced or omitted, and the order of some of the operation steps described may be interchangeable.

First, a substrate 102 is provided, and the buffer layer 104 is formed on the substrate 102. As mentioned above, the buffer layer 104 may have a single-layer or multi-layer structure. As shown in FIG. 6, in accordance with some embodiments, the buffer layer 104 may have a double-layer structure. The sub-layer 104a may be formed on the substrate 102 first, and then the sub-layer 104b may be formed on the sub-layer 104a. In accordance with some embodiments, the buffer layer 104 may be formed on the substrate 102 through a spin coating process, a chemical vapor deposition (CVD) process, another suitable method, or a combination thereof. The chemical vapor deposition process may include, for example, a low pressure chemical vapor deposition (LPCVD) process, a low temperature chemical vapor deposition (LTCVD) process, a rapid thermal chemical vapor deposition (RTCVD) process, a plasma enhanced chemical vapor deposition (PECVD) process, an atomic layer deposition (ALD) process, etc., but it is not limited thereto.

Next, an oxide semiconductor layer 300 may be formed on the buffer layer 104. The oxide semiconductor layer 300 has a first part 300a and second parts 300b adjacent to the first part 300a. The first part 300a can serve as a channel region, and the second part 300b can serve as a doped region with conductive properties (e.g., n-type or p-type). In accordance with some embodiments, the oxide semiconductor layer 300 may be formed by a chemical vapor deposition process, a physical vapor deposition (PVD) process, another suitable process, or a combination thereof. In addition, the second parts 300b may be doped with appropriate dopants through an ion implantation process.

Next, N₂ plasma treatment may be performed on the surface 300s of the oxide semiconductor layer 300. It should be noted that after the oxide semiconductor layer 300 is formed, further N₂ plasma treatment on the surface 300s of the oxide semiconductor layer 300 can passivate the dangling bonds on the surface 300s (such as forming SiN bonds), so defects on the surface 300s can be repaired. The stability of the positive-bias-temperature stress (PBTS) performance of the thin-film transistor can be improved, thereby improving the reliability of the electronic device 20.

Next, the insulating layer 106 may be formed on the oxide semiconductor layer 300. The insulating layer 106 may be overlapped with the first part 300a of the oxide semiconductor layer 300 and partially overlapped with the second part 300b of the oxide semiconductor layer 300. In accordance with some embodiments, the insulating layer 106 may be formed by a chemical vapor deposition process, a physical vapor deposition process, another suitable process, or a combination thereof. Moreover, the insulating layer 106 may be patterned through one or more photolithography processes and/or etching processes. In accordance with some embodiments, the photolithography process may include photoresist coating (e.g., spin coating), soft baking, hard baking, mask alignment, exposure, post-exposure baking, photoresist development, cleaning and drying, etc., but it is not limited thereto. The etching process may include a dry etching process or a wet etching process, but it is not limited thereto.

Specifically, in accordance with some embodiments, the step of forming the insulating layer 106 on the oxide semiconductor layer 300 includes introducing N₂O(g), SiH₄(g) and N₂(g) during the deposition process to form a first layer (e.g., lower part 106b), and introducing N₂O(g) and SiH₄(g) during the deposition process to form a second layer (e.g., upper part 106t) on the first layer.

The oxide semiconductor layer 300 and the insulating layer 106 are substantially completed through the aforementioned steps. In particular, in the mass spectrum measured by TOF-SIMS, the concentration of SiN— at the interface S1 between the first part 300a of the oxide semiconductor layer 300 and the insulating layer 106 is greater than the concentration of SiN— at the interface S2 between the first part 300a and the buffer layer 104. Furthermore, in the mass spectrum measured by TOF-SIMS, the concentration of SiN— in the lower part 106b is greater than the concentration of SiN— in the upper part 106t.

Next, a gate electrode 204 may be formed on the insulating layer 106, and the gate electrode 204 may be overlapped with the first part 300a of the oxide semiconductor layer 300. As mentioned above, the gate electrode 204 may have a single-layer or multi-layer structure. In accordance with some embodiments, the gate electrode 204 may be formed by a physical vapor deposition process, an electroplating process, an electroless plating process, another suitable method, or a combination thereof. Furthermore, the gate electrode 204 may be patterned through one or more photolithography processes and/or etching processes.

Furthermore, as shown in FIG. 6, in accordance with some embodiments, an insulating layer 108 may be further formed on the gate electrode 204. Specifically, the insulating layer 108 may be conformally formed on the buffer layer 104, the oxide semiconductor layer 300, the insulating layer 106 and the gate electrode 204. In accordance with some embodiments, the insulating layer 108 may be formed by a chemical vapor deposition process, a physical vapor deposition process, another suitable process, or a combination thereof. Moreover, the insulating layer 108 may be patterned through one or more photolithography processes and/or etching processes.

In detail, in accordance with some embodiments, N₂O(g), SiH₄(g) and N₂(g) may be introduced during the deposition process to form the insulating layer 108 on the gate electrode 204. Furthermore, a portion of the insulating layer 108 may be removed through a patterning process to form a via V1 exposing the second part 300b of the oxide semiconductor layer 300.

As mentioned above, the insulating layer 108 may have a third part 108p-1 (not labeled) that is overlapped with the gate electrode 204. In the mass spectrum measured by TOF-SIMS, the concentration of SiN— at the interface S3 between the third part 108p-1 and the gate electrode 204 is greater than the concentration of SiN— at the interface S1 between the first part 300a of the oxide semiconductor layer 300 and the insulating layer 106 (as shown in FIG. 4). Furthermore, the insulating layer 108 may have a fourth part 108p-2 (not labeled) that is overlapped with the second part 300b of the oxide semiconductor layer 300, and the fourth part 108p-2 has an upper portion Pa, a lower portion Pb, and a middle portion Pc disposed between on the upper portion Pa and the lower portion Pb. In the mass spectrum measured by TOF-SIMS, the concentration of SiN— in the lower portion Pb is greater than the concentration of SiN— in the middle portion Pc (as shown in FIG. 5).

In accordance with some embodiments, a metal layer 206 may be further formed on the insulating layer 108. The metal layer 206 may be filled in the via V1 of the insulating layer 108 and be electrically connected to the second part 300b of the oxide semiconductor layer 300. The metal layer 206 may have a single-layer or multi-layer structure. In accordance with some embodiments, the metal layer 206 may be formed by a physical vapor deposition process, an electroplating process, an electroless plating process, another suitable method, or a combination thereof. Furthermore, the metal layer 206 may be patterned through one or more photolithography processes and/or etching processes.

As shown in FIG. 6, compared with the electronic device 10, the electronic device 20 may not have the metal layer 202, and the thin-film transistor in the electronic device 20 has a top gate thin-film transistor structure. Furthermore, the first part 300a and the second part 300b of the oxide semiconductor layer 300 can serve as source/drain contacts and can be electrically connected to the source/drain electrode (not illustrated) through the metal layer 206.

To summarize the above, in accordance with the embodiments of the present disclosure, an electronic device is provided that includes an oxide semiconductor layer treated with a specific process, thereby improving the stability of the positive-bias-temperature stress (PBTS) performance of the thin-film transistor. The reliability or overall performance of the electronic device therefore can be improved.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a substrate;
a buffer layer disposed on the substrate;
an oxide semiconductor layer disposed on the buffer layer, having a first part and a second part adjacent to the first part;
a first insulating layer disposed on the oxide semiconductor layer; and
a gate electrode disposed on the first insulating layer and overlapped with the first part of the oxide semiconductor layer;
wherein an intensity of SiN— at an interface between the first part and the first insulating layer is greater than an intensity of SiN— at an interface between the first part and the buffer layer in a spectrum measured by TOF-SIMS.

2. The electronic device according to claim 1, wherein the first insulating layer has an upper part and a lower part, and an intensity of SiN— in the lower part is greater than an intensity of SiN— in the upper part in a spectrum measured by TOF-SIMS.

3. The electronic device according to claim 1, further comprising a second insulating layer (ILD) disposed on the gate electrode, the second insulating layer having a third part overlapped with the gate electrode, wherein an intensity of SiN— at an interface between the third part and the gate electrode is greater than an intensity of SiN— at the interface between the first part and the first insulating layer in a spectrum measured by TOF-SIMS.

4. The electronic device according to claim 1, wherein the second insulating layer has a fourth part overlapped with the second part of the oxide semiconductor layer, the fourth part has an upper portion, a lower portion, and a middle portion disposed therebetween, wherein an intensity of SiN— in the lower portion is greater than an intensity of SiN— in the middle portion in a spectrum measured by TOF-SIMS.

5. The electronic device according to claim 4, wherein the intensity of SiN— in the lower portion is greater than an intensity of SiN— in the upper portion in the spectrum measured by TOF-SIMS.

6. The electronic device according to claim 1, further comprising a second insulating layer disposed on the gate electrode, wherein the second insulating layer comprises silicon oxynitride (SiON).

7. The electronic device according to claim 1, further comprising a first metal layer overlapped with the oxide semiconductor layer, wherein the buffer layer is disposed between the first metal layer and the oxide semiconductor layer.

8. The electronic device according to claim 7, wherein the first metal layer comprises a double-layer structure with a lower layer of titanium and an upper layer of copper.

9. The electronic device according to claim 7, further comprising a second insulating layer disposed on the gate electrode and a second metal layer disposed on the second insulating layer, wherein the second metal layer is overlapped with the gate electrode.

10. The electronic device according to claim 1, wherein the oxide semiconductor layer comprises indium and gallium.

11. The electronic device according to claim 1, which is a display device.

12. The electronic device according to claim 1, wherein the buffer layer has a double-layer structure formed by a first sub-layer and a second sub-layer.

13. The electronic device according to claim 12, wherein the first sub-layer comprises silicon nitride, and the second sub-layer comprises silicon oxide.

14. A method of manufacturing an electronic device, comprising:
providing a substrate;
forming a buffer layer on the substrate;
forming an oxide semiconductor layer on the buffer layer, wherein the oxide semiconductor layer has a first part and a second part adjacent to the first part;
performing an N₂ plasma treatment on a surface of the oxide semiconductor layer;
forming a first insulating layer on the oxide semiconductor layer; and
forming a gate electrode on the first insulating layer and, wherein the gate electrode is overlapped with the first part of the oxide semiconductor layer.

15. The method according to claim 14, wherein a concentration of SiN— at an interface between the first part and the first insulating layer is greater than a concentration of SiN— at an interface between the first part and the buffer layer in a spectrum measured by TOF-SIMS.

16. The method according to claim 14, wherein the step of forming the first insulating layer on the oxide semiconductor layer comprises:
introducing N₂O(g), SiH₄(g) and N₂(g) in a deposition process to form a first layer; and
introducing N₂O(g) and SiH₄(g) in the deposition process to form a second layer on the first layer.

17. The method according to claim 16, wherein the first insulating layer has an upper part and a lower part, and a concentration of SiN— in the lower part is greater than a concentration of SiN— in the upper part in a spectrum measured by TOF-SIMS.

18. The method according to claim 14, further comprising forming a second insulating layer on the gate electrode by introducing N₂O(g), SiH₄(g) and N₂(g) in another deposition process.

19. The method according to claim 18, wherein the second insulating layer has a third part overlapped with the gate electrode, and a concentration of SiN— at an interface between the third part and the gate electrode is greater than a concentration of SiN— at the interface between the first part and the first insulating layer in a spectrum measured by TOF-SIMS.

20. The method according to claim 18, wherein the second insulating layer has a fourth part overlapped with the second part of the oxide semiconductor layer, the fourth part has an upper portion, a lower portion, and a middle portion disposed therebetween, wherein a concentration of SiN— in the lower portion is greater than a concentration of SiN— in the middle portion in a spectrum measured by TOF-SIMS.
